(19) United States
(12) Patent Application Publication
(10) Pub. No.: US 2006/0086957 A1
(43) Pub. Date: Apr. 27, 2006

(54) CMOS image sensor using reflection grating and method for manufacturing the same

(75) Inventor: Hwa-Young Kang, Suwon-si (KR)

Correspondence Address: CHA & REITER, LLC, 210 ROUTE 4 EAST STE 103, PARAMUS, NJ, 07652, US

(73) Assignee: Samsung Electronics Co.; LTD

(21) Appl. No.: 11/108,969

(22) Filed: Apr. 19, 2005

(30) Foreign Application Priority Data
Oct. 27, 2004 (KR) 2004-86305

(51) Int. Cl. H01L 31/113

(52) U.S. Cl. 257/292

(57) ABSTRACT

A CMOS image sensor having a reflection grating adapted to reflect and refract light not parallel to an optical axis is disclosed. The CMOS image sensor includes at least one photodiode, a photo-shielding film, a first interlayer insulation film, a color filter, a second interlayer insulation film, and at least one microlens, which are successively laminated on a substrate, and at least one reflection grating positioned between each microlens to reflect light which is incident through the edge of the lens in a direction not parallel to an optical axis and to refract the light with the grating so that the light is incident to the inside and is collected to the photodiode through the color filter.

### CLAIM OF PRIORITY

This application claims priority to an application entitled “CMOS Image Sensor Using Reflection Grating and Method for Manufacturing the Same,” filed with the Korean Intellectual Property Office on Oct. 27, 2004 and assigned Serial No. 2004-86305, the contents of which are hereby incorporated by reference.

### BACKGROUND OF THE INVENTION

1. Field of the Invention

The present invention relates to a CMOS image sensor using a reflection grating and a method for manufacturing the same. More particularly, the present invention relates to a CMOS image sensor having a reflection grating adapted to reflect and refract light that is not parallel to an optical axis and a method for manufacturing the same.

2. Description of the Related Art

In general, an image pickup device, also know as a camera lens module, is incorporated in a video camera, a digital still camera, a PC camera terminal, and a PDA to capture images. The camera lens module has an image sensor made of a semiconductor device for converting optical images into electrical signals.

The image sensor has a double CCD (charge-coupled device) positioned close to each MOS (metal oxide silicon) capacitor so that electron carriers can be stored and transferred in the capacitor. A CMOS (complementary metal oxide semiconductor) image sensor adopts a switching mode, wherein MOS transistors equal to the number of pixels are provided using a CMOS technology. The CMOS technique utilizes control circuits and signal processing circuits as peripheral circuits, and its output is detected successively using the MOS transistors.

Many efforts have been made to improve the photosensitivity of the CMOS image sensors as well as the light-collection technology. The CMOS image sensors include a photo-sensing unit for sensing light and a CMOS logic circuit unit for processing the sensed light into electrical signals and converting them into data. Although efforts are being made to increase the ratio of the area of the photo-sensing unit to the whole area of the image sensor (commonly referred to as “fill factor”) for improved photosensitivity, there exists a fundamental limitation as the logic circuit unit cannot be removed in the limited area. To this end, the light-collection technology, which changes the path of light incident on the region outside the photo-sensing unit and collects the light to the photo-sensing unit for improved photosensitivity, is widely studied recently.

FIG. 1 shows the main components of a known CMOS image sensor.

The CMOS image sensor includes at least one photo-sensing device 12 positioned on a semiconductor substrate 11; a photo-shielding film 13 positioned between each photo-sensing device 12; a first interlayer insulation film 14 positioned on the photo-sensing device 12 for insulation between films; a color filter 15 positioned on the first interlayer insulation film 14; a second interlayer insulation film 16 positioned on the color filter 15 for insulation between films; and a microlens 17 positioned on the second interlayer insulation film 16 and facing the color filter 15.

The photo-sensing device 12 is made up of a photodiode, and the photo-shielding film 13 is made up of a metal layer. The color filter 15 is usually made up of a photoresist which has been dyed a color capable of absorbing only a specific wavelength of light 20, and the microlens 17 is usually made up of a polymer-based resin.

The first and second interlayer insulation films 14 and 16 are transparent materials made up of silicon oxide film.

The incident light 20 passes through the microlens 17 and the corresponding red, green, and blue light are filtered by the respective red, green, and blue color filters. The filtered light is incident on the photodiode positioned beneath each color filter via the first interlayer insulation film 14. The photo-shielding film 13 prevents the incident light 20 from deviating from the path.

The conventional microlens configured as above must have optimum size, thickness, and radius of curvature, which are determined according to the construction specification of each photodiode (specifically the size, position and shape of unit pixel, the thickness of the photodiode, and the height, position and size of the photo-shielding film).

As stated earlier, the fill factor of the CMOS image sensor 10 refers to the ratio of the area of the photodiode 12, which is a light-collection device, to the whole area of a unit cell. As the number of pixels increases, more pixels must be integrated in a limited sensor area. As such, the fill factor then decreases gradually and the characteristics of photo-reception sensitivity deteriorate.

Although the fill factor may be improved by adopting a microlens 17 in the CMOS image sensor 10, there is a limitation in the improvement. In addition, when a lens 17 having small F# (an expression which indicates the brightness of the lens and represented by the ratio of the focal length to the diameter of incident light) is used, light 20 parallel to an optical axis is refracted by the lens 17 and reaches a color filter 15 and a photodiode 12 that faces face the lens 17. The device is operated normally in this case. However, when light 20 that is not parallel to the optical axis is refracted by the lens 17, he device is operated erroneously in this case as the light reaches the undesired area. Accordingly, there is a difference in the amount of light reaching the color filters 15 and the photodiodes 12. This degrades the light-collection efficiency and interferes with the smooth operation of the image sensor 10. As a result, poor images are displayed.

In order to solve the above stated drawbacks, smaller but more microlenses may be fastened to the sensor in the microlens process to improve the light-collection efficiency. However, the complicated lens process increases the process margin and the manufacturing cost.

### SUMMARY OF THE INVENTION

Accordingly, the present invention has been made to solve the above-mentioned problems occurring in the prior art and provides additional advantages, by providing a CMOS image sensor having a reflection grating adapted to reflect and refract light that is not parallel to an optical axis in order to improve the collection of incident light and a method for manufacturing the same.

One aspect of the present invention is to provide a CMOS image sensor having a reflection grating and a method for manufacturing the same, wherein a reflection grating is positioned between each lens during a microlens process so that any process failure caused by a lens fastened to each other can be avoided.

According to another aspect of the present invention, there is provided a CMOS image sensor including a substrate; at least one photodiode laminated on the substrate; a photo-shielding film laminated on the photodiode; a first interlayer insulation film laminated on the photo-shielding film; a color filter laminated on the firs interlayer insulation film; a second interlayer insulation film laminated on the color filter; at least one microlens laminated on the second interlayer insulation film; and at least one reflection grating positioned between each microlens to reflect light that is incident through the edge of the lens in a direction not parallel to an optical axis and to refract the light with the grating so that the light is incident to the inside and is collected to the photodiode through the color filter.

According to yet another aspect of the present invention, there is provided a method for manufacturing a CMOS image sensor including the steps of laminating at least photodiode and a first interlayer insulation film for insulation between layers thereon successively on a substrate; positioning a photo-shielding film between each photodiode and laminating a color filter thereon; laminating a second interlayer insulation film on the color filter; positioning at least one reflection grating on the second interlayer insulation film to reflect incident light and refract it with the grating; coating the top of the reflection grating with polymer for microlens fabrication; forming a resist pattern between each reflection grating from the polymer; and causing the resist pattern for microlens to flow and baking it at a high temperature.

### BRIEF DESCRIPTION OF THE DRAWINGS

The above features and advantages of the present invention will be more apparent from the following detailed description taken in conjunction with the accompanying drawings, in which:

FIG. 1 shows the construction of a conventional CMOS image sensor;

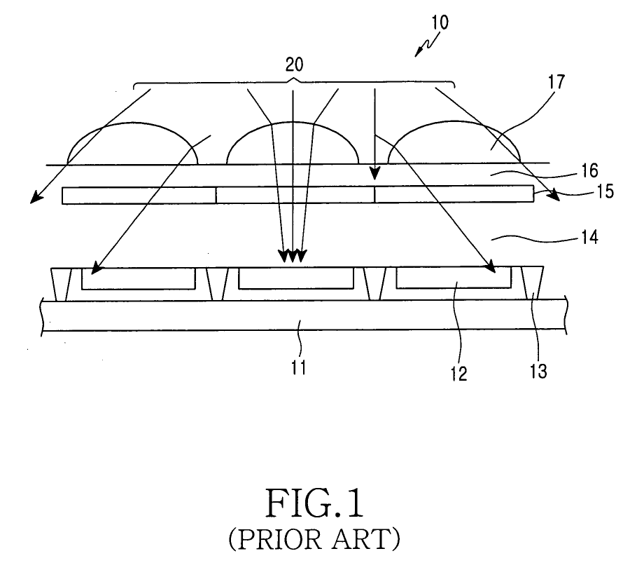

FIG. 2 shows the construction of a CMOS image sensor using a reflection grating according to an embodiment of the present invention;

FIG. 3 shows a process for laminating a reflection grating when manufacturing a CMOS image sensor using a reflection grating according to an embodiment of the present invention;

FIG. 4 shows a process for coating a reflection grating with polymer for microlens fabrication when manufacturing a CMOS image sensor using a reflection grating according to an embodiment of the present invention;

FIG. 5 shows a process for forming a resist pattern when manufacturing a CMOS image sensor using a reflection grating according to an embodiment of the present invention;

FIG. 6 shows a process for baking a resist pattern to fabricate a microlens when manufacturing a CMOS image sensor using a reflection grating according to an embodiment of the present invention; and

FIG. 7 is a flowchart showing the operation steps of manufacturing a CMOS image sensor using a reflection grating according to an embodiment of the present invention.

### DETAILED DESCRIPTION

Hereinafter, embodiments of the present invention will be described with reference to the accompanying drawings. For the purposes of clarity and simplicity, a detailed description of known functions and configurations incorporated herein will be omitted as it may make the subject matter of the present invention unclear.

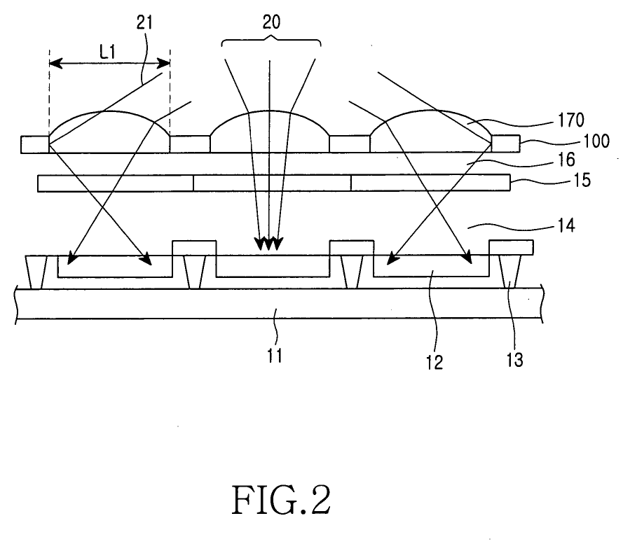

Referring to FIG. 2, a CMOS image sensor using a reflection grating according to an embodiment of the present invention includes at least one photodiode 12 and photo-shielding film 13 positioned on a substrate 11; a first interlayer insulation film 14 for insulation between layers; a color filter 15 positioned on the first interlayer insulation film 14; a second interlayer insulation film 16 positioned on the color filter 15 for insulation between layers; and at least one reflection grating 100 positioned on the second interlayer insulation film 16 to collect light incident through the edge of a lens 170 in a direction not parallel to an optical axis to the photodiode 12.

At least one microlens 170 is positioned between each reflection grating 100 so that light 20 and 21 can pass through. The reflection grating 100 is adapted to collect light 21 between the color filter 15 and the photodiode 12 and is positioned with a predetermined spacing L1 to separate the microlens 170. The microlens 17 is made up of a convex microlens 170.

Now, the operation of the CMOS image sensor using a reflection grating, configured as above, will now be described in more detail with reference to FIGS. 2 to 6.

As shown in FIG. 2, the CMOS image sensor has at least one photodiode 12 laminated on a substrate 11 to collect light 20 and 21, which is incident through a color filter 15, and a first interlayer insulation film 14 laminated on each photodiode 12 for insulation between layers.

A photo-shielding film 13 is positioned between each photodiode 12 to prevent the incident light 20 and 21 from deviating from the path.

A color filter 15 is laminated on the photo-shielding film 13, and a second interlayer insulation film 16 is laminated on the color filter 15 for insulation between layers.

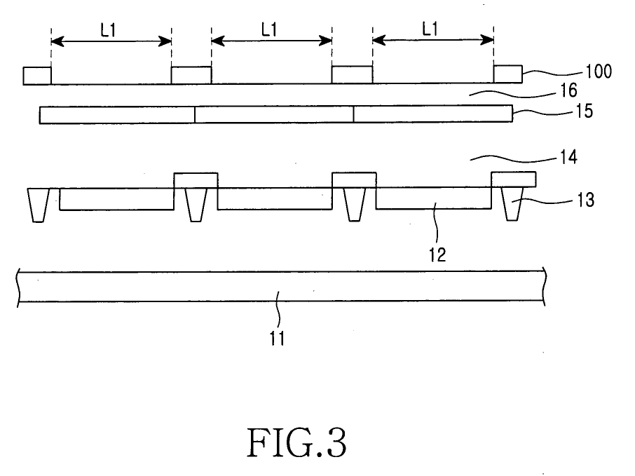

Referring to FIG. 3, at least one reflection grating 100 is positioned on the second interlayer insulation film 16 to reflect the incident light and refract it with the grating. The reflection grating 100 is positioned with a predetermined spacing L1 for a subsequent fabrication of a microlens 170.

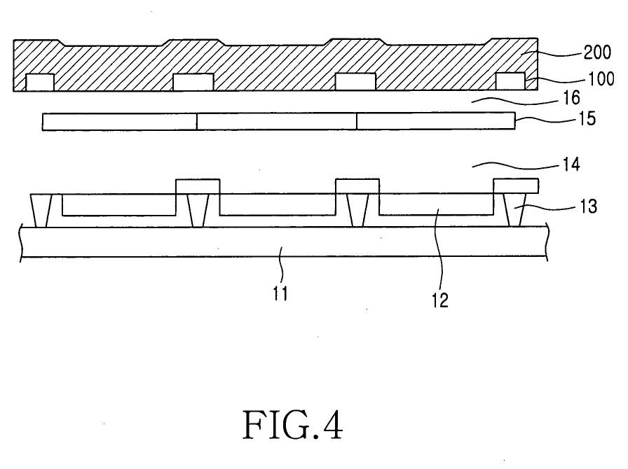

Referring to FIG. 4, the top surface of the reflection grating 100 is coated with a polymer 200 for microlens 170 fabrication.

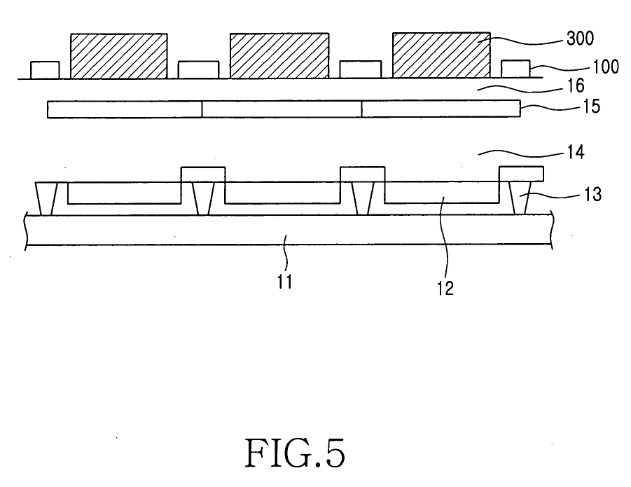

Referring to FIG. 5, a resist pattern 300 is formed between each reflection grating 100 in a square shape from the polymer 200.

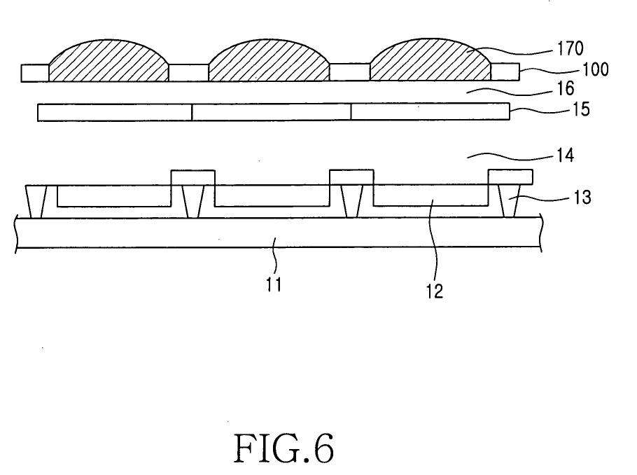

Referring to FIG. 6, the resist pattern 300 for microlens 170 is caused to flow and is baked at a high temperature in the range of 500° C.˜1200° C. The microlens 170 then becomes a convex lens as shown in FIG. 2. When light 20 and 21 is incident on the lens 170, light 20 parallel to the optical axis passes through the lens 170 and is refracted toward the inside. The light 20 is collected through the color filter 15 to the photodiode 12 positioned at the center.

If light 21 is incident on the lens 170 with a slant, i.e., in a direction not parallel to the optical axis, the light 21 is reflected by the reflection grating 100 and then refracted through the grating. As a result, the light is incident on the inside of each lens 170. The reflected and refracted light 21 is collected to the photodiode 12 through the color filter 15.

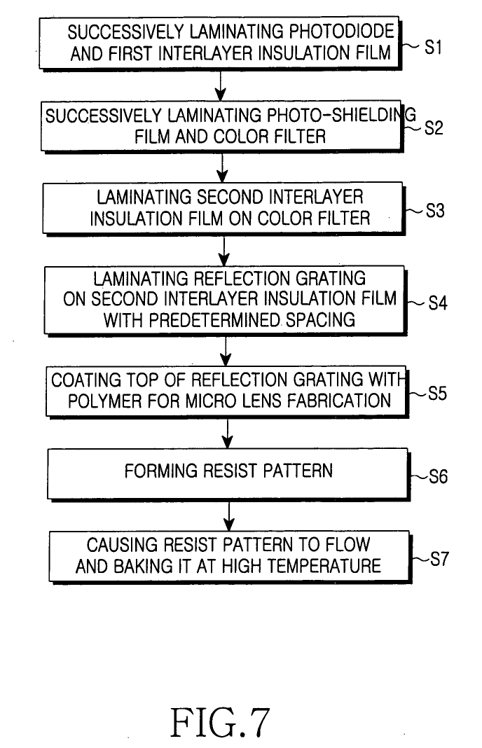

Referring to FIG. 7, the method of manufacturing a CMOS image sensor is described in more detail. First, at least one photodiode 12 is positioned on a substrate 11, and a first interlayer insulation film 14 is laminated on the photodiode 12 for insulation between layers (S1).

A photo-shielding film 13 is positioned between each photodiode 12, and a color filter 15 is laminated thereon (S2).

A second interlayer insulation film 16 is laminated on the color filter 15 (S3).

At least one reflection grating 100 is positioned on the second interlayer insulation film 16 to reflect incident light and refract it with the grating (S4).

The reflection grating 100 is positioned with a predetermined spacing L1 to place a microlens 170 between them.

The top of the reflection grating 100 is coated with polymer 200 for microlens 170 fabrication (S5).

A resist pattern 300 is formed in a square shape between each reflection grating 100 from the polymer 200 (S6).

The resist pattern 300 for microlens 170 is caused to flow and baked at a high temperature (S7).

The top surface of the microlens 170 is processed by clipping the top surface of the microlens to have a convex shape.

As mentioned above, the present invention provides a CMOS image sensor using a reflection grating adapted to reflect and refract light that is not parallel to an optical axis to achieve an improved collection of incident light and prevention of erroneous operation of the product.

While the invention has been shown and described with reference to certain preferred embodiments thereof, it will be understood by those skilled in the art that various changes in form and details may be made therein without departing from the spirit and scope of the invention as defined by the appended claims.

What is claimed is:

1. A CMOS image sensor comprising:
a substrate;
at least one photodiode laminated on the substrate;
a photo-shielding film laminated on the photodiode;
a first interlayer insulation film laminated on the photo-shielding film;
a color filter laminated on the firs interlayer insulation film;
a second interlayer insulation film laminated on the color filter;
at least one microlens laminated on the second interlayer insulation film; and
at least one reflection grating positioned between each microlens to reflect light incident through the edge of the lens in a direction not parallel to an optical axis and to refract the light with the grating, so that the light is incident to the inside and collected to the photodiode via the color filter.

2. The CMOS image sensor as claimed in claim 1, wherein the reflection grating is adapted to collect light between the color filter and the photodiode.

3. The CMOS image sensor as claimed in claim 1, wherein the reflection grating is positioned with a predetermined spacing to separate each of the microlens.

4. The CMOS image sensor as claimed in claim 1, wherein the microlens has a convex shape.

5. A method for manufacturing a CMOS image sensor, the method comprising the steps of:
laminating at least photodiode and a first interlayer insulation film for insulation between layers thereon successively on a substrate;
positioning a photo-shielding film between each photodiode and laminating a color filter thereon;
laminating a second interlayer insulation film on the color filter;
positioning at least one reflection grating on the second interlayer insulation film to reflect and refract the incident light with the grating;
coating the top of the reflection grating with polymer;
forming a resist pattern between each reflection grating from the polymer; and
causing the resist pattern for microlens to flow and baking at a predetermined temperature.

6. The method as claimed in claim 5, wherein, in the step of positioning at least one reflection grating on the second interlayer insulation film, each reflection grating is positioned apart with a predetermined spacing.

7. The method as claimed in claim 5, wherein, in the step of forming a resist pattern between each reflection grating from the polymer, the resist pattern is formed in a square shape.

8. The method as claimed in claim 5, wherein in the step of baking the top surface of the resist pattern for microlens at a high temperature, the top surface of the microlens has a convex shape.
